(19) United States
(12) Patent Application Publication
(10) Pub. No.: US 2015/0349157 A1
(43) Pub. Date: Dec. 3, 2015

(54) THIN FILM COMPOUND SEMICONDUCTOR SOLAR CELLS

(71) Applicant: HANBAT NATIONAL UNIVERSITY INDUSTRY - ACADEMIC COOPERATION FOUNDATION, Daejeon (KR)

(72) Inventor: Choong-Heui Chung, Seoul (KR)

(21) Appl. No.: 14/712,765

(22) Filed: May 14, 2015

(30) Foreign Application Priority Data
Jun. 2, 2014 (KR) 10-2014-0066711

(51) Int. Cl. H01L 31/0224; H01L 31/0392

(52) U.S. Cl. CPC H01L 31/022433; H01L 31/03923

(57) ABSTRACT

Provided is a thin film solar cell including: a substrate on which a rear surface electrode is formed; a light absorbing layer, which is a compound semiconductor, positioned on the rear surface electrode; and a composite layer positioned on the light absorbing layer and contacting the light absorbing layer, wherein the composite layer includes: a conductive mesh; and a semiconductor material filled in at least an empty space of the conductive mesh.

### CROSS-REFERENCE TO RELATED APPLICATIONS

This application claims priority under 35 U.S.C. §119 to Korean Patent Application No. 10-2014-0066711, filed on Jun. 2, 2014, in the Korean Intellectual Property Office, the disclosure of which is incorporated herein by reference in its entirety.

### TECHNICAL FIELD

The following disclosure relates to a thin film compound semiconductor solar cell, and more particularly, to a thin film compound semiconductor solar cell appropriate for mass production and commercialization by having a very simple structure.

### BACKGROUND

Recently, in accordance with an increase in an interest in an environment problem and exhaustion of natural resources, an interest in a solar cell has increased as an alternative energy source that does not cause environmental pollution and has high energy efficiency. The solar cell is classified into a silicon semiconductor solar cell, a compound semiconductor solar cell, a tandem solar cell, and the like, depending on components thereof, and since the compound semiconductor solar cell such as a CIGS (CuInGaSe) solar cell has efficiency similar to that of the silicon semiconductor solar cell and is very electro-optically stable, it has been prominent as the next-generation solar cell that may substitute for the silicon semiconductor solar cell.

However, in the compound semiconductor solar cell, a stack structure of a substrate, a rear surface electrode, a light absorbing layer, a buffer layer, a window layer having a multilayer structure, a metal grid electrode, and the like, is complicated, a large amount of investment of an initial equipment such as an elaborate vacuum equipment is required in order to manufacture the respective layers, and a process having a very low mass production feature, such as an electron beam evaporation process, is required, which hinder commercialization of the compound semiconductor solar cell.

In Korean Patent Laid-Open Publication No. 2013-0040385, a technology of using a carbon nanotube as an electrode in order to implement a flexible solar cell and decrease a cost has been suggested. However, the solar cell suggested in Korean Patent Laid-Open Publication No. 2013-0040385 has also a stack structure of basic six layers such as the substrate, the rear surface electrode, the light absorbing layer, the buffer layer, the window layer having the multilayer structure, and the metal grid electrode, such that it has a limitation in commercialization.

### RELATED ART DOCUMENT

### Patent Document

Korean Patent Laid-Open Publication No. 2013-0040385

### SUMMARY

An embodiment of the present invention is directed to providing a thin film compound semiconductor solar cell capable of simplifying a manufacturing process, decreasing a cost, and being advantageous for commercialization by having a very simple stack structure.

In one general aspect, a thin film solar cell includes: a substrate on which a rear surface electrode is formed; a light absorbing layer, which is a compound semiconductor, positioned on the rear surface electrode; and a composite layer positioned on the light absorbing layer and contacting the light absorbing layer, wherein the composite layer includes: a conductive mesh; and a semiconductor material filled in at least an empty space of the conductive mesh.

The compound semiconductor may be made of a copper-indium-gallium-chalcogen compound or a copper-zinc-tin-chalcogen compound.

The conductive mesh of the composite layer may be a network of one or more nanostructures selected from the group consisting of a metal wire, a metal tube, a carbon nanotube, and a graphene.

The semiconductor material of the composite layer may include an intrinsic semiconductor; an extrinsic n-type semiconductor; or both of the intrinsic semiconductor and the extrinsic n-type semiconductor.

In the semiconductor material of the composite layer, a concentration of an n-type dopant may be changed in a thickness direction, which is a direction from a surface of the composite layer contacting the light absorbing layer toward a surface of the composite layer opposing the surface of the composite layer contacting the light absorbing layer.

The concentration of the n-type dopant may be continuously or discontinuously increased in the thickness direction.

The composite layer may include a first semiconductor material covering an entire surface of the light absorbing layer exposed to at least the empty space of the conductive mesh and a second semiconductor material positioned on the first semiconductor material.

The first semiconductor material may be one or two or more materials selected from the group consisting of ZnO_{1-y}S_{y} (y is a real number satisfying 0.1≦y≦0.5), ZnS, CdS, ZnₓCd₁₋ₓS (x is a real number satisfying 0<x<1), In₂S₃, SnS₂, CdSe, and ZnSe, and the second semiconductor material may be the first semiconductor material containing an n-type dopant.

The conductive mesh may be a network of one or more nanostructures selected from the group consisting of a metal wire, a metal tube, a carbon nanotube, and a graphene.

The thin film solar cell may further include an n-type semiconductor layer or an auxiliary layer, which is a transparent conductive layer, positioned on the composite layer.

### BRIEF DESCRIPTION OF THE DRAWINGS

FIG. 1 is a cross-sectional view of a thin film solar cell according to the related art.

FIG. 2 is a cross-sectional view of a thin film solar cell according to an exemplary embodiment of the present invention.

FIG. 3 is a view illustrating only a composite layer in the solar cell according to the exemplary embodiment of the present invention in detail.

FIG. 4 is a view illustrating an example of a concentration profile of an n-type dopant of a semiconductor layer based on a composite layer thickness t of the composite layer illustrated in FIG. 3.

FIG. 5A is another cross-sectional view illustrating a composite layer in the thin film solar cell according to the exemplary embodiment of the present invention, and FIGS. 5B and 5C are views illustrating examples of a concentration profile of an n-type dopant depending on a composite layer thickness t of a semiconductor layer.

FIGS. 6A and 6B are cross-sectional views of the thin film solar cell according to the exemplary embodiment of the present invention.

FIG. 7 is another cross-sectional view of the thin film solar cell according to the exemplary embodiment of the present invention.

### DETAILED DESCRIPTION OF EMBODIMENTS

Hereinafter, a thin film solar cell according to exemplary embodiments of the present invention will be described in detail with reference to the accompanying drawings. The drawings to be provided below are provided by way of example so that the idea of the present invention can be sufficiently transferred to those skilled in the art to which the present invention pertains. Therefore, the present invention is not limited to the drawings provided below but may be modified in many different forms. In addition, the drawings suggested below will be exaggerated in order to clear the spirit and scope of the present invention. Technical terms and scientific terms used in the present specification have the general meaning understood by those skilled in the art to which the present invention pertains unless otherwise defined, and a description for the known function and configuration unnecessarily obscuring the gist of the present invention will be omitted in the following description and the accompanying drawings.

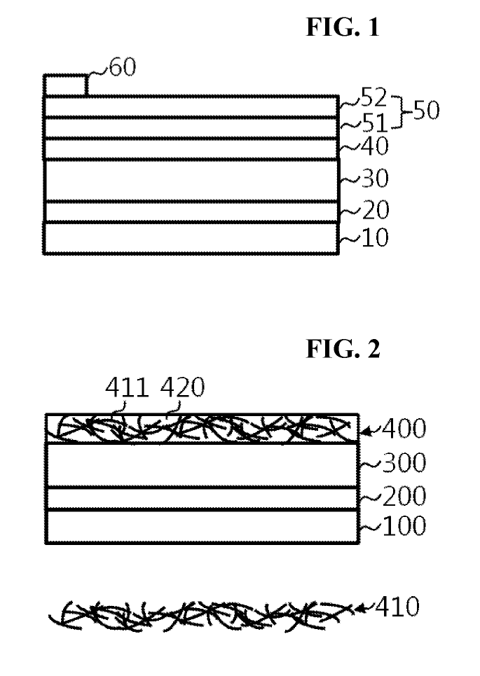

FIG. 1 is a view illustrating a basic structure of a compound semiconductor solar cell known in the related art. As illustrated in FIG. 1, a general compound semiconductor solar cell has a stack structure including a substrate 10, a rear surface electrode 20 including Mo, a compound semiconductor light absorbing layer 30, a buffer layer 40, a window layer (transparent window layer) 50, a front surface metal (metal grid) 60 or a stack structure further including an anti-reflective layer (not illustrated) disposed between the window layer 50 and the front surface metal 60 in addition to these components, wherein the window layer 50 also uses generally a stack thin film of intrinsic-ZnO (i-ZnO) 51 and ZnO 52 doped with Al (ZnO:Al).

The compound semiconductor solar cell has been prominent as a cell that is the most promising in terms of commercialization due to efficiency high enough to substitute for a silicon solar cell and a low material cost. However, in order to commercialize the compound semiconductor solar cell based on mass production, a high level evaporation process should be excluded, if possible, and the compound semiconductor solar cell should be able to be manufactured by a process as simple as possible. The buffer layer may be manufactured using a chemical bath deposition (CBD) method, and in the case of using the CBD method, a buffer layer having the most excellent performance may be manufactured. However, in order to manufacture the transparent window, which is a stack thin film of i-ZnO and Al:ZnO, evaporation is required, and in the case of an anti-reflective layer or a front surface metal, electron beam evaporation is required.

The present applicant has filed the present patent by developing a structure that may significantly improve productivity at the time of manufacturing a compound semiconductor solar cell, may decrease a cost required for building up a process, may not require a multi-step strict process control, may minimize a deposition process, and may have power generation efficiency similar to that of a compound semiconductor solar cell according to the related art due to a very simple structure as a result of performing a study for a long period of time in order to develop a structure that may commercialize the compound semiconductor solar cell.

A thin film solar cell according to an exemplary embodiment of the present invention may include a substrate on which a rear surface electrode is formed; a light absorbing layer, which is a compound semiconductor, positioned on the rear surface electrode; and a composite layer positioned on the light absorbing layer and contacting the light absorbing layer, wherein the composite layer may include a conductive mesh; and a semiconductor material filled in at least an empty space of the conductive mesh. The composite layer may serve as all of at least the buffer layer, the window layer, and the front surface metal according to the related art by the conductive mesh and the semiconductor material filled in the empty space of the conductive mesh.

FIG. 2 is a cross-sectional view of a thin film solar cell according to the exemplary embodiment of the present invention. As in an example illustrated in FIG. 2, the thin film solar cell according to the exemplary embodiment of the present invention may include the substrate 100 on which the rear surface electrode 200 is formed; the light absorbing layer 300, which is the compound semiconductor, positioned on the rear surface electrode 200; and the composite layer 400 contacting the light absorbing layer 300 and positioned on the light absorbing layer 300, wherein the composite layer 400 may include the conductive mesh 410; and the semiconductor material 420 filled in at least an empty space of the conductive mesh 410.

The substrate 100 may serve as a support, and may include a rigid substrate or a flexible substrate. A specific example of the rigid substrate may include a glass substrate including soda-lime glass, a ceramic substrate such as alumina, stainless steel, and a metal substrate such as copper, and a specific example of the flexible substrate may include a polymer substrate such as polyimide. However, the present invention is not limited by the materials of the substrate.

The rear surface electrode 200 is made of any material that has high electrical conductivity, may be ohmically bonded to a compound semiconductor, and is stable under a chalcogen atmosphere, and is made of any material that is used in a general compound semiconductor solar cell. A specific example of a material of the rear surface electrode may include molybdenum (Mo). However, the present invention is not limited by the material of the rear surface electrode. A thickness of the rear surface electrode may be any thickness used in the general compound semiconductor solar cell, and a specific and non-restrictive example of the thickness of the rear surface electrode may be 0.5 to 2 μm. However, the present invention is not limited by the thickness of the rear surface electrode.

The rear surface electrode may be formed on the substrate using any known method of forming a metal layer. In detail, a known chemical deposition method, a known physical deposition method, or the like, may be used. As an example, a deposition method such as a sputtering method, an evaporation method, a metal organic chemical vapor deposition (MOCVD) method, or a molecular beam epitaxy (MBE) method may be used.

A compound semiconductor configuring the light absorbing layer 300 may mean a layer of a chalcogen compound of copper and one or two or more elements selected from groups XII to XIV elements. In detail, the compound semiconductor may include a copper-indium-gallium-chalcogen compound or a copper-zinc-tin-chalcogen compound. In more detail, a material of the compound semiconductor may be CIGS (Cu—In—Ga—Se or Cu—In—Ga—S), CIGSS (Cu—In—Ga—Se—S), CZTS (Cu—Zn—Sn—Se or Cu—Zn—Sn—S), or CZTSS (Cu—Zn—Sn—Se—S). In more detail, a material of the compound semiconductor may be CuInₓGa₁₋ₓSe₂ (x is a real number satisfying 0<x<1), CuInₓGa₁₋ₓS₂ (x is a real number satisfying 0<x<1), CuInₓGa₁₋ₓ(Se_{y}S_{1-y})₂ (x is a real number satisfying 0<x<1 and y is a real number satisfying 0<y<1), Cu₂ZnₓSn₁₋ₓSe₄ (x is a real number satisfying 0<x<1), Cu₂ZnₓSn₁₋ₓS₄ (x is a real number satisfying 0<x<1), or Cu₂ZnₓSn₁₋ₓ(Se_{y}S_{1-y})₄ (x is a real number satisfying 0<x<1 and y is a real number satisfying 0<y<1), but is not limited thereto. That is, a material of the compound semiconductor may be any material used as a material of the light absorbing layer in the general compound semiconductor solar cell. A thickness of the light absorbing layer may be any thickness used in the general compound semiconductor solar cell, and a specific and non-restrictive example of the thickness of the light absorbing layer may be 1.5 to 3 μm. However, the present invention is not limited by the thickness of the light absorbing layer.

As a method of manufacturing the light absorbing layer, a known method of manufacturing a CIGS or CZTS light absorbing layer may be used. For example, a method of growing a light absorbing layer known in Korean Patent Laid-Open Publication No. 2009-0043245, U.S. Pat. No. 7,547,569, U.S. Pat. No. 6,258,620, and U.S. Pat. No. 5,981,868 may be used. As a non-restrictive example, the light absorbing layer may be manufactured using an evaporation method, a sputtering+selenization method, an electro-deposition method, an ink printing method of applying, reacting, and sintering precursor ink in a powder or colloid state, a spray pyrolysis method, or the like.

The composite layer 400 may include the conductive mesh 410 and the semiconductor material 420 filled in at least the empty space of the conductive mesh 410. The conductive mesh 410 may be a network of one or more nanostructures 411 selected from the group consisting of a metal wire, a metal tube, a carbon nanotube, and a graphene.

The conductive mesh 410 of the composite layer 400 may serve to collect a photocurrent formed in the light absorbing layer 300, and may also serve as a terminal for moving the current to the outside of the cell. The semiconductor material 420 filled in at least the empty space of the conductive mesh 410 may serve to provide a movement path of electrons among electrons (serve as electronic carriers) and holes formed in the light absorbing layer 300 at the time of absorbing light, and may also serve to provide a current movement path to the conductive mesh in a region corresponding to the empty space of the conductive mesh 410. That is, when a stack direction of the light absorbing layer 300 and the composite layer 400 is called a vertical direction, the semiconductor material 420 filled in the empty space of the conductive mesh 410 may serve to separate and move the electrons among the electrons and the holes formed in the light absorbing layer 300 in the vertical direction, and may also serve to provide a low resistance path through which the separated electrons may move to the conductive mesh.

The nanostructures 411 configuring the conductive mesh 410 of the composite layer 400 may include one-dimensional nanostructures including a metal wire, a metal tube, and a carbon nanotube and/or two-dimensional nanostructures such as a graphene, and a network of the nanostructures may mean a structure in which the nanostructures continuously contact each other to provide a current movement path in an in-plane direction of the composite layer and in the in-plane direction and a thickness direction (shortest distance direction from a surface of the composite layer contacting the light absorbing layer to a surface of the composite layer opposing the surface of the composite layer contacting the light absorbing layer) of the composite layer. As a specific example, the network of the nanostructures may have a structure in which the one-dimensional nanostructures and/or the two-dimensional nanostructures are irregularly tangled while contacting each other. A metal of a metal nanowire or a metal nanotube may be one or two or more materials selected from the group consisting of gold, silver, aluminum, and copper, or be any material that is stable even in a nano dimension such as a nanowire or a nanotube and has excellent electrical conductivity. The carbon nanotube may be a single-walled type, a double-walled type, a thin multi-walled type, a multi-walled type, a roped type, or a mixture thereof. The graphene may be a single layer graphene, a multilayer graphene, or a mixture thereof.

In the case in which the composite layer includes the one-dimensional nanostructures, lengths of the one-dimensional nanostructures may be 10 to 100 μm in terms of forming a stable network of the nanostructures, and an aspect ratio of the one-dimensional nanostructures may be 100 to 1000 in terms of providing a smooth current movement path by a simple contact between the nanostructures. In the case in which the composite layer includes the two-dimensional nanostructures including the graphene, a length of the longest side of the graphene may be 10 to 100 μm.

In the composite layer, a surface coverage, which is an area of a surface of the light absorbing layer covered by the conductive mesh on a projection image of the conductive mesh based on the surface of the light absorbing layer, may be 1 to 15%. In detail, the surface coverage may be (value obtained by dividing the area of the light absorbing layer covered by the conductive mesh on the projection image of the conductive mesh by a surface of the light absorbing layer contacting the composite layer)*100%. Here, the projection image of the conductive mesh may be a two-dimensional image of the conductive mesh formed by irradiating parallel light to the conductive mesh positioned on the light absorbing layer in a direction perpendicular to the surface of the light absorbing layer. In the case in which the conductive mesh has the above-mentioned surface coverage, a conductive network may be stably formed, a contact area between the semiconductor materials of the light absorbing layer and the composite layer may be maximized, and a decrease in light transmittance by the composite layer may be prevented. Here, the composite layer may contain the conductive mesh so that the surface coverage is 5 to 15%, preferably, 8 to 15% in terms of directly connecting an external conducting wire on the surface of the composite layer without additionally forming a metal grid electrode to make an electrical connection to the outside of the cell. Here, in the case in which the composite layer contains the conductive mesh (nanostructures) so that the surface coverage is 1% or more, the conductive mesh, which is a network of the nanostructures may have a sheet resistance of several tens of Ω/□ or less. In the case in which the composite layer contains the conductive mesh (nanostructures) so that the surface coverage is 5 to 15%, preferably, 8 to 15%, the conductive mesh may have a sheet resistance of several Ω/□ or less, such that it may have electrical conductivity that is similar to or the same as that of the metal grid electrode.

A thickness of the composite layer may be varied to some degree depending on a semiconductor material to be described below, but may be 50 to 500 nm. In the case in which a thickness of the composite layer is less than 50 nm, which is very thin, a resistance of the composite layer is increased, such that there is a risk that a photocurrent will be lost, and in the case in which a thickness of the composite layer exceeds 500 nm, which is very thick, light transmittance is decreased, such that there is a risk that efficiency of the cell will be again decreased.

The semiconductor material 420 filled in at least the empty space of the conductive mesh 410 may be a semiconductor material that may contact the light absorbing layer so as to accord with an operation principle of the solar cell to form a p-n junction and may serve as an electric charge carrier carrying photo-charges formed in the light absorbing layer to the conductive mesh. Preferably, since the chalcogen compound of the copper and one or two or more elements selected from the groups XII to XIV elements is a p-type semiconductor material, the semiconductor material 420 contained in the composite layer 400 may be an n-type semiconductor material.

The semiconductor material 420 filled in the empty space of the conductive mesh 410 may include an intrinsic semiconductor; an extrinsic n-type semiconductor; or both of the intrinsic semiconductor and the extrinsic n-type semiconductor.

The intrinsic semiconductor means a semiconductor that is not artificially doped with a dopant (impurities) in order to adjust electrical characteristics. However, it is not to be interpreted that the intrinsic semiconductor does not contain impurities at all. That is, the intrinsic semiconductor may contain a small amount of impurities caused by a raw material or a manufacturing process. The extrinsic n-type semiconductor may mean a semiconductor containing an n-type dopant. In the case in which the light absorbing layer is the CIGS or CZTS light absorbing layer, the intrinsic semiconductor may be made of one or two or more materials selected from the group consisting of ZnO_{1-y}S_{y} (y is a real number satisfying 0.1≦y≦0.5), ZnS, CdS, ZnₓCd₁₋ₓS (x is a real number satisfying 0<x<1), In₂S₃, SnS₂, CdSe, and ZnSe in order to form the p-n junction with the light absorbing layer to separate and move electrons from the light absorbing layer. In the case in which the light absorbing layer is the CIGS or CZTS light absorbing layer, the extrinsic n-type semiconductor may be the above-mentioned extrinsic semiconductor containing an n-type dopant. In detail, the extrinsic n-type semiconductor may be made of one or two or more materials selected from the group consisting of ZnO_{1-y}S_{y} (y is a real number satisfying 0.1≦y≦0.5), ZnS, CdS, ZnₓCd₁₋ₓS (x is a real number satisfying 0<x<1), In₂S₃, SnS₂, CdSe, and ZnSe containing an n-type dopant. The n-type dopant may be one or two or more elements selected from the group consisting of Al, Ga, B, Sn, Sb, F, Cl, Mn, Co, Ni, Fe, Ti, Mo, Nb, P, O, In, Cr, and Zn, more specifically, one or two or more elements selected from the group consisting of Ga, Al, B In, F, Cr, and Zn. As a specific and non-restrictive example, a material of the extrinsic n-type semiconductor may be CdS doped with one or more elements selected from the group consisting of Ga, Al, B, In, F, Cr, and Zn, or ZnS doped with one or more elements selected from the group consisting of Al, B, and F. However, the present invention is not limited by the above-mentioned semiconductor materials. As an example, the intrinsic semiconductor may be made of a material used as a material of the buffer layer of the solar cell including the CIGS or CZTS light absorbing layer according to the related art, and the extrinsic n-type semiconductor may be made of a material produced by adding the n-type dopant to the semiconductor material used as the material of the buffer layer of the solar cell including the CIGS or CZTS light absorbing layer according to the related art or a material used as a material of the window layer.

Since the above-mentioned composite layer substitutes for the metal grid electrode, the window layer, and the buffer layer according to the related art, the thin film solar cell according to the exemplary embodiment of the present invention has a very simple stack structure of the substrate, the rear surface electrode, the light absorbing layer, and the composite layer, such that a device structure and a manufacturing process may be simplified. Therefore, the solar cell may be mass-produced at a low cost, which may be very useful for commercialization. The thin film solar cell according to the exemplary embodiment of the present invention may have efficiency similar to that of the compound semiconductor solar cell according to the related art in spite of having the very simple stack structure of the substrate, the rear surface electrode, the light absorbing layer, and the composite layer, may be implemented at a thinner thickness due to the very simple stack structure, and may be appropriate for being flexibly implemented.

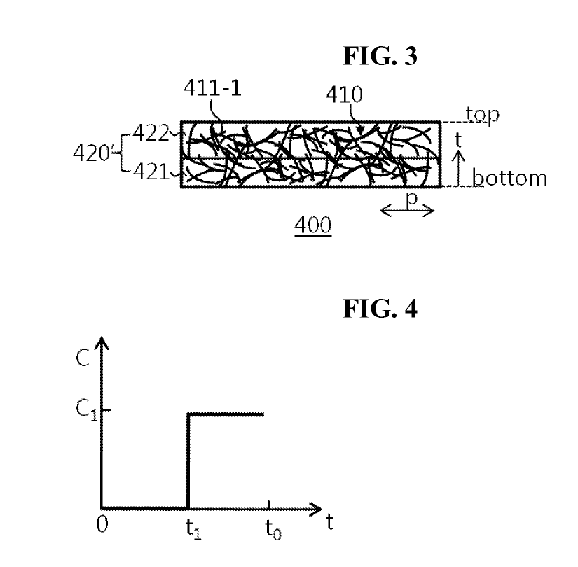

Next, in the thin film solar cell according to the exemplary embodiment of the present invention, a more preferable structure of the composite layer will be described in detail with reference to a view illustrating only the composite layer in detail. Here, a bottom surface (illustrated as bottom in FIG. 3) of the composite layer is a surface of the composite layer contacting the light absorbing layer, and a direction from the bottom surface of the composite layer toward a top surface (illustrated as top in FIG. 3) thereof is the thickness direction (illustrated as an arrow t in FIG. 3). In addition, although an example in which a framework of the composite layer is defined by the conductive mesh, such that the composite layer contains the semiconductor material has been described, since the semiconductor material filled in the empty space of the conductive mesh forms a continuum film, the semiconductor material filled in the empty space of the conductive mesh will be called a semiconductor layer. That is, the composite layer may be interpreted as a structure in which the conductive mesh is embedded in the semiconductor layer. In addition, although the composite layer has been illustrated below based on the case in which the conductive mesh is formed of silver nanowires, which is one-dimensional nanostructures, this is to assist in the understanding of the present invention. That is, the present invention is not limited by a kind of nanostructures configuring the conductive mesh.

FIG. 3 is a cross-sectional view illustrating a composite layer 400 in the thin film solar cell according to the exemplary embodiment of the present invention. As in an example illustrated in FIG. 3, the conductive mesh 410 may include silver nanowires 411-1 irregularly contacting each other in the in-plane direction (arrow p direction of FIG. 3) and the thickness direction (arrow t direction of FIG. 3) and provide a low impedance path in the in-plane direction and the thickness direction.

A semiconductor material of a semiconductor layer 420′ may be filled in at least an empty space between the silver nanowires 411-1 and contact the light absorbing layer 300. In the example illustrated in FIG. 3, the semiconductor layer 420′ may include at least one intrinsic semiconductor layer (first semiconductor material layer) 421 and at least one extrinsic n-type semiconductor layer (second semiconductor material layer) 422, wherein the intrinsic semiconductor layer 421 may be positioned at a lower portion in the thickness direction (arrow t direction of FIG. 3), and the extrinsic n-type semiconductor layer 422 may be positioned at an upper portion in the thickness direction.

That is, the semiconductor layer 420′ may include the intrinsic semiconductor layer 421 contacting the light absorbing layer 300 and the extrinsic n-type semiconductor layer 422 positioned on the intrinsic semiconductor layer 421.

As in the example illustrated in FIG. 3, the intrinsic semiconductor layer 421 may be a single layer made of one or two or more materials selected from the group consisting of ZnO_{1-y}S_{y} (y is a real number satisfying 0.1≦y≦0.5), ZnS, CdS, ZnₓCd₁₋ₓS (x is a real number satisfying 0<x<1), In₂S₃, SnS₂, CdSe, and ZnSe or a stack layer including layers each made of one or two or more materials selected from the group consisting of ZnO_{1-y}S_{y} (y is a real number satisfying 0.1≦y≦0.5), ZnS, CdS, ZnₓCd₁₋ₓS (x is a real number satisfying 0<x<1), In₂S₃, SnS₂, CdSe, and ZnSe.

The intrinsic semiconductor layer 421 may serve to form the p-n junction with the light absorbing layer, to alleviate a lattice constant difference between the extrinsic n-type semiconductor layer 422 and the light absorbing layer 300, and/or to arrange an energy band structure with the light absorbing layer in order to smoothly move electric charges. In terms of forming the p-n junction, stably alleviating the lattice constant difference, and stably arranging the energy band structure, a thickness of the intrinsic semiconductor layer 421 may be 10% to 50% (0.1 t₀ to 0.5t₀) of a total thickness (t₀) of the composite layer.

The extrinsic n-type semiconductor layer 422 may serve to provide a low impedance path through which a photocurrent may smoothly move from a semiconductor material region to the conductive mesh. That is, the composite layer includes the extrinsic n-type semiconductor layer 422, such that smooth movement of the photocurrent in the in-plane direction (arrow p direction of FIG. 3) of the composite layer may be secured.

As in the example illustrated in FIG. 3, the extrinsic n-type semiconductor layer 422 may be a single layer in which one or two or more materials selected from the group consisting of ZnO_{1-y}S_{y} (y is a real number satisfying 0.1≦y≦0.5), ZnS, CdS, ZnₓCd₁₋ₓS (x is a real number satisfying 0<x<1), In₂S₃, SnS₂, CdSe, and ZnSe are doped with the n-type dopant or a stack layer including layers in which two or more materials selected from the group consisting of ZnO_{1-y}S_{y} (y is a real number satisfying 0.1≦y≦0.5), ZnS, CdS, ZnₓCd₁₋ₓS (x is a real number satisfying 0<x<1), In₂S₃, SnS₂, CdSe, and ZnSe are doped with the n-type dopant, respectively. Here, the n-type dopant may be one or two or more elements selected from the group consisting of Al, Ga, B, Sn, Sb, F, Cl, Mn, Co, Ni, Fe, Ti, Mo, Nb, P, O, In, Cr, and Zn, more specifically, one or two or more elements selected from the group consisting of Ga, Al, B In, F, Cr, and Zn. In terms of providing a stable current movement path of the photocurrent, a sheet resistance of the extrinsic n-type semiconductor layer is 1 GΩ/□, preferably, 10MΩ/□ or less, which may be varied to some degree depending on a size of the empty space of the conductive mesh, and the extrinsic n-type semiconductor layer may contain the n-type dopant so as to satisfy the above-mentioned sheet resistance. Here, a thickness of the extrinsic n-type semiconductor layer 422 may be 50% to 90% (0.5t₀ to 0.9t₀) of the total thickness (t₀) of the composite layer.

FIG. 4 is a view illustrating an example of a concentration profile of an n-type dopant of a semiconductor layer 420′ based on a composite layer thickness t of the composite layer illustrated in FIG. 3. In FIG. 4, t₁ is a position of an interface on which the intrinsic semiconductor layer and the extrinsic n-type semiconductor layer contact each other, and C₁ is a concentration of an n-type dopant of the extrinsic n-type semiconductor layer. As illustrated in FIG. 4, in terms of the n-type dopant, the example of FIG. 3 may correspond to an example of a structure in which the composite layer 400 includes the semiconductor layer 420′ of which the n-type dopant is discontinuously increased in the thickness direction of the composite layer 400.

In the example illustrated in FIG. 3, the intrinsic semiconductor layer may serve as the buffer layer according to the related art, the extrinsic n-type semiconductor layer combined with the conductive mesh may serve as the window layer according to the related art, and the conductive mesh itself may serve as the metal grid according to the related art. Therefore, a structure corresponding to the stack structure of the metal grid, the window layer, the buffer layer, and the light absorbing layer known as the most effective structure in the related art may be implemented by a single composite layer. In addition, since the photocurrent formed in the light absorbing layer flows from the light absorbing layer to the intrinsic semiconductor layer of the composite layer, flows from the intrinsic semiconductor layer to the extrinsic n-type semiconductor layer, and flows from the extrinsic n-type semiconductor layer to the conductive mesh, the thin film solar cell according to the exemplary embodiment of the present invention may have an energy band structure (structure formed by energy bands of each layer configuring the solar cell) that is the same as or is similar to that of the stack structure of the metal grid, the window layer, the buffer layer, and the light absorbing layer according to the related art in terms of the photocurrent.

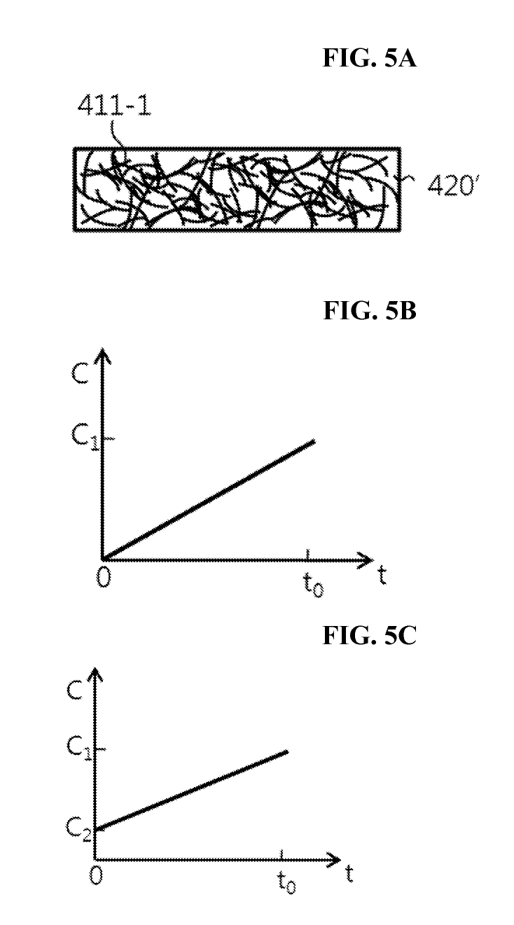

FIG. 5A is another cross-sectional view illustrating a composite layer 400 in the thin film solar cell according to the exemplary embodiment of the present invention. As in an example illustrated in FIGS. 5B and 5C, the composite layer 400 may include a conductive mesh 410 and a semiconductor layer 420′, wherein the semiconductor layer 420′ may have a concentration profile of an n-type dopant continuously increased in the thickness direction of the composite layer.

In detail, FIGS. 5B and 5C are examples illustrating a concentration profile of an n-type dopant depending on a composite layer thickness t of the semiconductor layer. In FIGS. 5B and 5C, t=0 means an interface between the light absorbing layer and the composite layer, and t=t₀ means a surface of the composite layer.

As in an example illustrated in FIG. 5B, in the semiconductor layer 420′, the light absorbing layer and an intrinsic semiconductor in a state in which it is not doped (doping concentration=0) contact each other to form an interface, and a concentration of an n-type dopant may be continuously increased as a thickness of the composite layer is increased. As in an example illustrated in FIG. 5C, in the semiconductor layer 420′, the light absorbing layer and an n-type semiconductor in a state in which it is doped with the n-type dopant (doping concentration=C₂) contact each other to form an interface, and a concentration of an n-type dopant may be continuously increased as a thickness of the composite layer is increased. Although the case in which the concentration of the n-type dopant is linearly increased has been illustrated in FIGS. 5B and 5C, the concentration profile of the n-type dopant may be varied in consideration of securing a smooth flow of the photocurrent, a lattice constant difference from the light absorbing layer within the composite layer, an energy band structure, and a pre-designed thickness of the composite layer. As an example, in the case in which the composite layer is to be implemented at a thin thickness, a concentration profile of the n-type dopant may be exponentially increased. Here, as described above, although a sheet resistance of the semiconductor layer may be varied to some degree depending on a size of the empty space of the conductive mesh, it is preferable that a sheet resistance of a semiconductor material doped at the highest concentration within at least a semiconductor layer region positioned on the top surface, that is, the composite layer is 1GΩ/□ or less. As a specific example, in the case in which the surface coverage, which is the area of the surface of the light absorbing layer covered by the conductive mesh on the projection image of the conductive mesh based on the surface of the light absorbing layer, is a relatively large surface coverage of 5% or more, specifically, 8% or more, and more specifically, 10% or more, the sheet resistance of the semiconductor material doped at the highest concentration within the composite layer may be 1GΩ/□ or less, and in the case in which the surface coverage is a relatively small surface coverage less than 5%, specifically, of 1%, the sheet resistance of the semiconductor material doped at the highest concentration within the composite layer may be 10MΩ/□ or less.

In FIGS. 5A to 5C, a lower region of the semiconductor layer that is not doped or is doped at a low concentration may serve as the buffer layer according to the related art, and an upper region of the semiconductor layer that is combined with the conductive mesh and is doped at a high concentration (doped so that a sheet resistance is 1GΩ/□ or less, preferably, 10MΩ/□ or less) may serve as the window layer according to the related art, such that the structure corresponding to the stack structure of the metal grid, the window layer, the buffer layer, and the light absorbing layer according to the related art may be implemented by the single composite layer, as described above with reference to FIG. 4. Meanwhile, FIG. 4 illustrates the composite layer having the structure similar or corresponding to the stack structure of the metal grid, the window layer, the buffer layer, and the light absorbing layer according to the related art through a structure in which the concentration of the n-type dopant is discontinuously changed, while FIG. 5A illustrates the composite layer having the structure similar or corresponding to the stack structure of the metal grid, the window layer, the buffer layer, and the light absorbing layer according to the related art through a structure in which the concentration of the n-type dopant is continuously changed.

The composite layer may be formed by a method of applying the nanostructures forming the conductive mesh onto the light absorbing layer to form the conductive mesh and then forming the semiconductor material on the conductive mesh. The nanostructures may be applied by a spin coating method, a spray coating method, a dip coating method, a vacuum filtration method, a Meyer rod coating method, or the like.

The semiconductor material may be formed by methods known in the related art used in order to deposit the semiconductor material. Among the methods in the related art, an appropriate method may be used in consideration of physical characteristics of the semiconductor material that is to be deposited. The semiconductor material may be deposited by a chemical bath deposition (CBD) method, a successive ionic layer adsorption and reaction (SILAR) method, a spin coating method, a spray coating method, a dip coating method, a chemical vapor deposition (metal organic chemical vapor deposition) method, an atomic layer deposition method, a sputtering (reactive sputtering) method, an evaporation deposition method, an oxidation method, a sulfuration method, or the like, as a specific example. Further, in the case in which the intrinsic semiconductor material and the extrinsic n-type semiconductor materials are the same semiconductor material, the composite layer may be formed by only whether or not the n-type dopant is supplied or adjusting a supplied amount of the n-type dopant. Therefore, the composite layer may be formed by a more economical and simpler process. In detail, in a process of depositing the semiconductor material, an n-type dopant material or a precursor thereof is supplied, thereby making it possible to adjust the concentration of the n-type dopant of the deposited semiconductor material. It is controlled whether or not the n-type dopant material or the precursor thereof is supplied, thereby making it possible to manufacture the composite layer having the concentration profile of the n-type dopant that is discontinuously changed as illustrated in FIG. 4, and a supplied amount of the n-type dopant material or the precursor thereof is controlled, thereby making it possible to manufacture the composite layer having the concentration profile of the n-type dopant that is continuously changed as illustrated in FIGS. 5A to 5C.

The solar cell according to the exemplary embodiment of the present invention may not include the metal grid electrode. In detail, the thin film compound semiconductor solar cell according to the related art generally includes the metal grid electrode disposed on a dual stack film of i-ZnO and n-type ZnO and collecting the photocurrent. However, in the solar cell according to the exemplary embodiment of the present invention, as described above, the conductive mesh itself provided in the composite layer may serve as the metal grid, such that the metal grid electrode may not be provided on the composite layer. However, in order to form a more stable electrical connection to the outside of the cell, the metal grid electrode may be selectively formed on the composite layer in consideration of a purpose and a use environment of the cell. The metal grid electrode may be made of a material used in a metal grid electrode positioned on the window layer in the compound semiconductor solar cell and serving to collect the photocurrent, have a structure of the metal grid electrode, and may be manufactured by a known method.

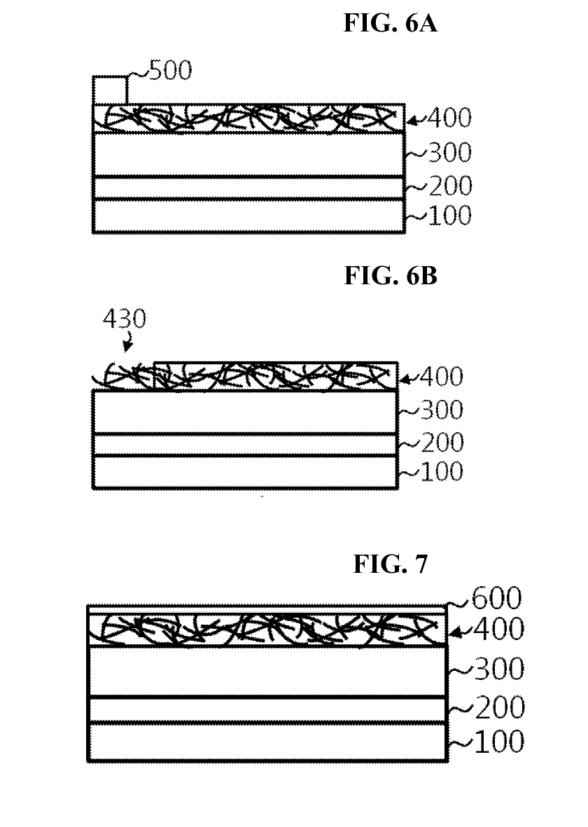

FIGS. 6A and 6B are cross-sectional views of the thin film solar cell according to the exemplary embodiment of the present invention, wherein FIG. 6A illustrates an example in which a metal grid electrode 500 is provided on the composite layer 400, and FIG. 6B illustrates an example in which a terminal region 430 for an electrical connection to the outside is formed in the composite layer 400. As in an example illustrated in FIG. 6A, the metal grid electrode 500 may be provided on the composite layer 400 in order to form a more stable electrical connection to the outside of the cell. Here, the metal grid electrode 500 may be in a state in which it is connected to the conductive mesh 410 of the composite layer 400. As in an example illustrated in FIG. 6B, the semiconductor material may not be formed in a partial region of the composite layer 400 for the purpose of an electrical connection to the outside. That is, the composite layer 400 may include the terminal region 430 for the electrical connection to the outside, wherein the terminal region 430 may be formed of the conductive mesh itself. The terminal region 430 may be designed in consideration of a purpose and modularization of the solar cell, and be easily formed by shading the terminal region at the time of depositing the semiconductor material of the composite layer to prevent the semiconductor material from being deposited.

FIG. 7 is a cross-sectional view of the solar cell according to the exemplary embodiment of the present invention. As in an example illustrated in FIG. 7, the solar cell according to the exemplary embodiment of the present invention may further include an n-type semiconductor layer 600 positioned on the composite layer 400. The current may more stably and smoothly move from the semiconductor material of the composite layer 400 to the conductive mesh by the n-type semiconductor layer 600 positioned on the composite layer 400. In detail, the n-type semiconductor layer 600 formed on the composite layer 400 so as to contact the composite layer 400 may receive photo-charges from the semiconductor material 420 of the composite layer 400 and move the photo-charges to the conductive mesh 410 of the composite layer, thereby enabling smoother movement of the photo-charges in the in-plane direction (arrow p direction of FIG. 3).

In terms of the semiconductor material, the semiconductor material 420 of the composite layer 400 and the n-type semiconductor layer 600 may be integral with each other. That is, in a step of depositing the semiconductor material on the conductive mesh 410 in order to form the composite layer 400, the semiconductor material is deposited so as to cover the entire conductive mesh 410, such that the n-type semiconductor layer 600 may be formed integrally with the semiconductor material 420 of the composite layer. Here, the n-type semiconductor layer 600 may be made of a material that is the same as that of the extrinsic n-type semiconductor layer of the composite layer described above. However, in terms of securing more stable movement of the current in the in-plane direction, a concentration of the n-type dopant in the n-type semiconductor layer may be relatively higher than that of the n-type dopant in the extrinsic n-type semiconductor layer of the composite layer.

The solar cell according to the exemplary embodiment of the present invention may further include an auxiliary layer, which is a transparent conductive layer, positioned on the n-type semiconductor layer 600 based on FIG. 7 or positioned on the composite layer 400 so as to contact the composite layer 400. In detail, the auxiliary layer may be made of a transparent conductive material, and smoother movement of the photocurrent in the in-plane direction (arrow p direction of FIG. 3) may be secured by the auxiliary layer.

In detail, the auxiliary layer may be made of one or two or more materials selected from the group consisting of indium tin oxides (ITOs), fluorinated tin oxides (FTOs), aluminum zinc oxides (AZOs), gallium zinc oxides (GZOs), tin oxides (SnO₂), zinc oxides (ZnO), and a mixture thereof.

The auxiliary layer or the n-type semiconductor layer described above, which may be selectively provided on the composite layer in order to improve the movement of the photocurrent in the in-plane direction, has natural electrical conductivity of materials configuring the auxiliary layer or the n-type semiconductor layer. In addition, a thickness of the auxiliary layer or the n-type semiconductor layer is not particularly limited as long as light transmission is not hindered. As a specific example, a thickness of the auxiliary layer or the n-type semiconductor layer may be 50 nm to 1 μm, but is not limited thereto.

The thin film solar cell according to the exemplary embodiment of the present invention may have the very simple stack structure since the stack structure of the metal grid, the window layer, and the buffer layer according to the related art is implemented by the composite layer. Therefore, the device structure and the manufacturing process may be simplified, such that the solar cell may be mass-produced at a low cost, which may be useful for commercialization. In addition, the thin film solar cell may have efficiency similar to that of the solar cell according to the related art including the substrate, the rear surface electrode, the light absorbing layer, the buffer layer, the window layer having a multilayer structure, and the metal grid electrode in spite of having a simple structure of the substrate, the rear surface electrode, the light absorbing layer, and the composite layer, and may be appropriate particularly for a flexible solar cell since it has the very simple stack structure.

Hereinabove, although the present invention has been described by specific matters, exemplary embodiments, and drawings, they have been provided only for assisting in the entire understanding of the present invention. Therefore, the present invention is not limited to the exemplary embodiments. Various modifications and changes may be made by those skilled in the art to which the present invention pertains from this description.

Therefore, the spirit of the present invention should not be limited to these exemplary embodiments, but the claims and all of modifications equal or equivalent to the claims are intended to fall within the scope and spirit of the present invention.

What is claimed is:

1. A thin film solar cell comprising:
a substrate on which a rear surface electrode is formed;
a light absorbing layer, which is a compound semiconductor, positioned on the rear surface electrode; and
a composite layer positioned on the light absorbing layer and contacting the light absorbing layer,
wherein the composite layer includes:
a conductive mesh; and
a semiconductor material filled in at least an empty space of the conductive mesh.

2. The thin film solar cell of claim 1, wherein the compound semiconductor is made of a copper-indium-gallium-chalcogen compound or a copper-zinc-tin-chalcogen compound.

3. The thin film solar cell of claim 2, wherein the semiconductor material of the composite layer includes an intrinsic semiconductor; an extrinsic n-type semiconductor; or both of the intrinsic semiconductor and the extrinsic n-type semiconductor.

4. The thin film solar cell of claim 2, wherein in the semiconductor material of the composite layer, a concentration of an n-type dopant is changed in a thickness direction, which is a direction from a surface of the composite layer contacting the light absorbing layer toward a surface of the composite layer opposing the surface of the composite layer contacting the light absorbing layer.

5. The thin film solar cell of claim 4, wherein the concentration of the n-type dopant is continuously or discontinuously increased in the thickness direction.

6. The thin film solar cell of claim 2, wherein the composite layer includes a first semiconductor material covering an entire surface of the light absorbing layer exposed to at least the empty space of the conductive mesh and a second semiconductor material positioned on the first semiconductor material and filled in a remaining empty space of the conductive mesh.

7. The thin film solar cell of claim 6, wherein the first semiconductor material is one or two or more materials selected from the group consisting of ZnO_{1-y}S_{y} (y is a real number satisfying 0.1≦y≦0.5), ZnS, CdS, ZnₓCd₁₋ₓS (x is a real number satisfying 0<x<1), In₂S₃, SnS₂, CdSe, and ZnSe, and the second semiconductor material is the first semiconductor material containing an n-type dopant.

8. The thin film solar cell of claim 2, wherein the conductive mesh is a network of one or more nanostructures selected from the group consisting of a metal wire, a metal tube, a carbon nanotube, and a graphene.

9. The thin film solar cell of claim 1, further comprising an n-type semiconductor layer or an auxiliary layer, which is a transparent conductive layer, positioned on the composite layer.
